(19) United States
(12) Patent Application Publication
(10) Pub. No.: US 2006/0134559 A1
(43) Pub. Date: Jun. 22, 2006

(54) Method for forming patterns on a semiconductor device

(76) Inventor: Jeong Hyuk Ha, Incheon city (KR)

Correspondence Address: MCKENNA LONG & ALDRIDGE LLP, 1900 K STREET, NW, WASHINGTON, DC, 20006, US

(21) Appl. No.: 11/246,239

(22) Filed: Oct. 11, 2005

(30) Foreign Application Priority Data
Dec. 21, 2004 (KR) 10-2004-0109604

(51) Int. Cl. G03F 7/00

(52) U.S. Cl. 430/312; 430/394

(57) ABSTRACT

A method for fabricating patterns of a semiconductor device to obtain the minute line width and to improve the characteristics of a device includes coating a first photoresist on a wafer, coating a second photoresist on the first photoresist, selectively exposing the second photoresist to light having a first wavelength, selectively exposing the first photoresist to light having a second wavelength, wherein the second wavelength is shorter than the first wavelength, and forming first and second photoresist patterns by developing the exposed first and second photoresists.

### CROSS-REFERENCE TO RELATED APPLICATIONS

This application claims the benefit of Korean Application No. P2004-109604 filed on Dec. 21, 2004, which is hereby incorporated by reference as if fully set forth herein.

### BACKGROUND OF THE INVENTION

1. Field of the Invention

The present invention relates to a method for fabricating a semiconductor device, and more particularly, to a method for fabricating patterns of a semiconductor device to obtain a minute line width and to improve the characteristics of the device.

2. Discussion of the Related Art

Generally, a photoresist mask is used when performing an etching process to form lines and contact holes (or via holes) among the various steps of forming a semiconductor device.

When forming a semiconductor device, a liquid crystal display and a thin film magnetic head using a photolithography process an exposure apparatus is used. A light beam is provided to a wafer using an optical apparatus to create patterns in a photo mask or a reticle that has been deposited on the wafer.

When forming the patterns of the semiconductor device using the photolithography-process according to the related art, the photoresist is divided into two.

First, when using an I-line process, the photoresist is coated on the wafer, and it is then selectively exposed to a light having a wavelength of 365 nm using an I-line exposure apparatus. The light transmitted to the wafer through a photo-mask (reticle) forms patterns on the wafer because it causes the exposed portion of the photoresist to chemically react with a developer and melt. A developer may be formed of a liquid type material including TMAH.

To obtain the minute line width, the process involves the use of DUV (Deep UV) that has a wavelength of 248 nm. The photoresist is selectively exposed to DUV, and the exposed portion of the photoresist reacts with the developer, thereby forming the desired pattern. The developer may be formed of a liquid type material including TMAH.

In the photo-process according to the related art, I-line and DUV are selectively used according to the line width of the desired pattern. If the line width of the pattern is large, the I-line process is used. Instead, if a minute pattern is desired, the DUV process is performed.

Accordingly, the process of the related art is complicated because when forming the respective patterns, it is necessary to select one between the I-line process and the DUV process depending to the appropriate CD (Critical Dimension).

### SUMMARY OF THE INVENTION

Accordingly, the present invention is directed to a method for fabricating patterns of a semiconductor device that substantially obviates one or more problems due to limitations and disadvantages of the related art.

One advantage of the present invention is that it can provide a method for fabricating patterns of a semiconductor device to obtain the minute line width and to improve the characteristics of device.

Additional examples of features and advantages of the invention will be set forth in the description which follows, and in part will become apparent from the description, or by practice of the invention.

To achieve these and other advantages and in accordance with an embodiment of the present invention, as embodied and broadly described herein, a method for forming patterns of semiconductor device includes coating a first photoresist on a wafer; coating a second photoresist on the first photoresist; selectively exposing the second photoresist to light of a first wavelength; selectively exposing the first photoresist to light of a second wavelength, wherein the second wavelength is shorter than the first wavelength; and forming first and second photoresist patterns by developing the exposed first and second photoresists.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principle of the invention.

In the drawings:

FIG. 1 is a schematic view of an exposure apparatus used in the present invention;

FIG. 2 is a cross sectional view of patterns of a semiconductor device fabricated in a method according to the present invention; and

FIGS. 3A to 3C are cross sectional views of the process for forming patterns of a semiconductor device according to the present invention.

### DETAILED DESCRIPTION OF THE INVENTION

Reference will now be made in detail to some embodiments of the present invention, examples of which are illustrated in the accompanying drawings. Wherever possible, the same reference numbers will be used throughout the drawings to refer to the same or like parts.

Hereinafter, patterns of a semiconductor device and a method for forming the same according to the present invention will be described with reference to the accompanying drawings.

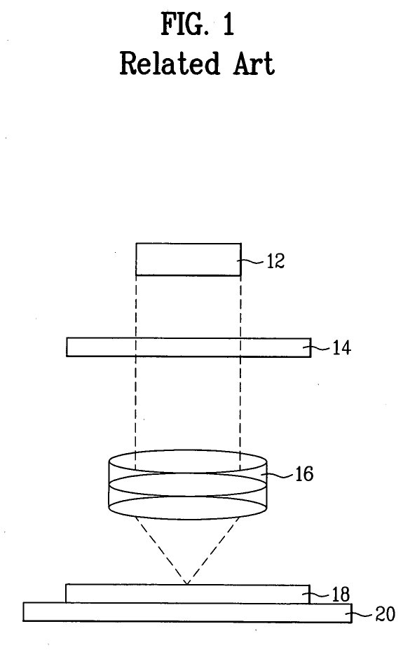

FIG. 1 is a schematic view of an exposure apparatus used in the present invention.

As shown in FIG. 1, the exposure apparatus of the present invention is provided with a lamp 12, a reticle 14, a reduction projection-type lens 16, and a stage 20. The lamp 12 emits the light that goes through the reticle 14 having the predetermined pattern for a corresponding circuit that is provided below the lamp 12. The reduction projection-type lens 16 is provided below the reticle 14, wherein the reduction projection-type lens 16 reduces the image made in the reticle 14 with the light emitted from the lamp 12, so as to print the image on a substrate as desired by repeating the process as necessary. The stage 20 is provided below the reduction projection-type lens 16 and a wafer 18 is loaded onto the stage 20. The reduction projection-type lens 16 has a fixed focus. Thus, the reduction projection-type lens 16 may be focused by moving the stage 20 up and down.

The wafers 18 may have different thicknesses and the flatness may be non-uniform. To focus the reduction projection-type lens 16, the distance between the reduction projection-type lens 16 and the upper surface of the wafer loaded onto the stage 20 must be maintained. Accordingly, the distance between the reduction projection-type lens 16 and the upper surface of the wafer loaded onto the stage 20 may need to be adjusted. This may be accomplished by moving the stage 20.

The reticle 14 may be formed by providing an opaque metal thin film on a glass substrate, and then selectively exposing a predetermined portion of the opaque metal thin film to an E-beam. The opaque metal thin film remains in the portion not to be irradiated with the E-beam. The pattern on the reticle 14 is formed to be five to ten times larger than the pattern to be formed on the wafer 18.

With the aforementioned exposure apparatus, the patterns may be formed on the wafer in the following method.

First, the wafer 18 is coated with a photoresist and it is loaded onto stage 20. Then, the reticle 14, having the predetermined circuit pattern, is loaded to a reticle loading part.

After that, the lamp 12 emits the light of short wavelength toward the reticle 14. The pattern of reticle 14 is reduced to the predetermined ratio (for example, 5/1 or 10/1) by the reduction projection-type lens 16, and it is then printed on the wafer.

The light does not pass through the opaque metal thin film portion of reticle 14. The light only passes through the portion of reticle 14 from which the opaque thin film has been removed. In this manner it is possible to selectively expose the photoresist provided on the wafer 18. Subsequently, the selectively exposed photoresist is developed, thereby forming a predetermined photoresist pattern on the wafer.

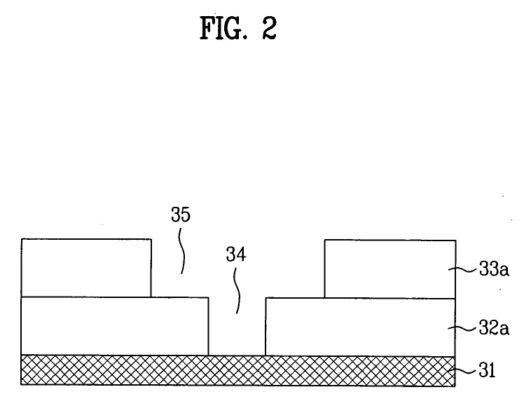

FIG. 2 is a cross sectional view of the patterns of the semiconductor device according to the present invention.

As shown in FIG. 2, the patterns of the semiconductor device according to the present invention include a first photoresist pattern 32a and a second photoresist pattern 33a. The first photoresist pattern 32a has a first opening 34 formed by performing an exposure process with DUV. The second photoresist pattern 33a has a second opening 35 formed exposing the first photoresist pattern 32a with a I-line process. The second opening 35 of the second photoresist pattern 33a is wider than the first opening 34 of the first photoresist pattern 32a.

Each of the first and second openings 34 and 35 has the predetermined width suitable for the size of the pattern formed by the following process.

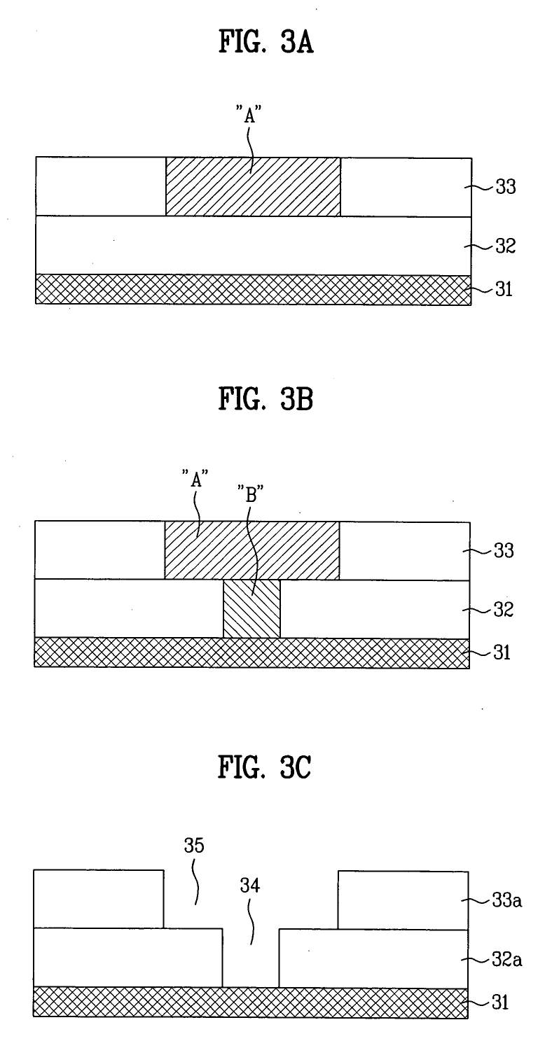

FIGS. 3A to 3C are cross sectional views of the process for forming patterns in a semiconductor device according to the present invention.

As shown in FIG. 3A, a first photoresist 32 is coated on the wafer 31, wherein the first photoresist 32 is exposed to DUV. In this case, the first photoresist 32 may be coated by spin-coating, spray-coating, or dip-coating. The spin-coating method, in which the photoresist is coated on the wafer 31 while rotating the wafer 31 at a high speed, is advantageous in that it can result in greater stability and uniformity.

A second photoresist 33 is coated on the first photoresist 32, wherein the second photoresist 33 is exposed with a I-line process.

The wafer 31 coated with the first and second photoresists 32 and 33 is moved to an I-line exposure apparatus. Then, a first reticle (not shown) with a first pattern is positioned above the second photoresist 33, and a I-line is irradiated to the entire surface including the first reticle, thereby selectively exposing the second photoresist 33.

Area “A” corresponds to the portion exposed to I-line irradiation.

As shown in FIG. 3B, after completing the exposure process with the I-line exposure apparatus, the wafer 31 is moved to a DUV exposure apparatus. A second reticle (not shown) of a second pattern is positioned above the second photoresist 33, and DUV is irradiated to the entire surface including the second reticle, thereby selectively exposing the first photoresist 32. In this case, the second pattern of the second reticle is smaller than the first pattern of the first reticle.

Area “B” corresponds to the portion exposed to DUV.

As shown in FIG. 3C, first and second photoresist patterns 32a and 33a are formed by developing the exposed first and second photoresists 32 and 33, wherein the first and second photoresist patterns 32a and 33a respectively have first and second openings 34 and 35.

The first opening 34 is formed in the first photoresist pattern 32a, wherein the first opening 34 is positioned to correspond with the second pattern. Also, the second opening 35 is formed in the second photoresist pattern 33a, wherein the second opening 35 is provided to correspond with the first pattern.

The first and second photoresists 32 and 33 may be developed in a dipping method or a spraying method. In a dipping method, it is difficult to control the temperature, the density and the temporal variation. Instead, in a spraying method, it is possible to control the temperature, the density and the temporal variation. The spraying method may use an In-line type apparatus.

The developer for the first and second photoresists 32 and 33 is formed of a liquid type material including TMAH.

It is possible to form the desired pattern by using the first and second photoresist patterns 32a and 33b as masks.

As mentioned above, the method for forming the patterns of semiconductor device according to the present invention has at least the following advantages.

In the method for forming the patterns of semiconductor device according to the present invention, the patterns may be formed in shape of steps with the exposure apparatus and the photoresist. Also, by decreasing the line width in the gate or metal patterning process, the cross section increases, thereby it is possible to fabricate a semiconductor device more economically.

To obtain the minute line width and to improve the characteristics of device having a small CD, the process of the present invention may use DUV. If the CD is large, the process of the present invention may use I-line. It is possible, therefore, to obtain a simplified process.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for forming patterns of semiconductor device comprising:
coating a first photoresist on a wafer;
coating a second photoresist on the first photoresist;
selectively exposing the second photoresist to a light having a first wavelength;
selectively exposing the first photoresist to a light having a second wavelength, wherein the second wavelength is shorter than the first wavelength; and
forming first and second photoresist patterns by developing the exposed first and second photoresists.

2. The method of claim 1, wherein the first and second photoresists are coated with a spin-coating method.

3. The method of claim 1, wherein the light having the first wavelength corresponds to an I-line process.

4. The method of claim 1, wherein the light having the second wavelength corresponds to a DUV (Deep UV) process.

5. The method of claim 1, wherein the first photoresist is exposed at a portion corresponding to the exposed portion of the second photoresist, and the exposed portion of the first photoresist is smaller than the exposed portion of the second photoresist.
